(19) United States
(12) Patent Application Publication
(10) Pub. No.: US 2025/0336340 A1
(43) Pub. Date: Oct. 30, 2025

(54) SYSTEMS, DEVICES, AND METHODS FOR REDUCING LED DISPLAY BRIGHTNESS

(71) Applicant: MEDIA RESOURCES INC., Oakville (CA)

(72) Inventors: Cheng Liang QIAN, Oakville (CA); Jeff RUSHTON, Salmon Arm (CA); Yong PENG, Oakville (CA)

(21) Appl. No.: 19/194,844

(22) Filed: Apr. 30, 2025

Related U.S. Application Data
(60) Provisional application No. 63/640,294, filed on Apr. 30, 2024.

(51) Int. Cl. G09G 3/32; H10H 29/34

(52) U.S. Cl. CPC G09G 3/32; H10H 29/34; G09G 2300/0452; G09G 2320/064; G09G 2320/068; G09G 2360/144

(57) ABSTRACT

Described herein are systems, devices, and methods for a LED display including: at least one pixel, each pixel having three subchannels arranged in a triangular configuration; and a control system configured to actuate any one or more of a downsampling mode or a temporal scanning mode of the LED display. The subchannels can be arranged in a triangular configuration, with a height less than its width, and with a blue LED positioned below a red LED and a green LED.

### CROSS-REFERENCE TO RELATED APPLICATION

This application claims priority to U.S. Provisional Application Ser. No. 63/640,294, filed Apr. 30, 2024, the entire disclosure of which is hereby incorporated by reference.

### FIELD

The present disclosure relates in general to the field of LED light displays and more particularly to directing the light emission from LED light displays for the purpose of reducing light pollution by the LED light displays during nighttime use.

### BACKGROUND

Prior art light-emitting diode (LED) light displays are flat panel displays that incorporate an array of light-emitting diodes to produce a display, for example, such as a visual display of information. The diodes function as pixels in the display. The brightness of a LED light display allows it to be used outdoors or indoors. LED light displays are commonly utilized as store signs, billboards, destination signs on public transport vehicles, and for other purposes of displaying information to an audience. LED light displays are further utilized to provide illumination that may be decorative or technical, such as stage lighting or seasonal display lighting.

Generally, a LED light display emits light from the entire forward side of the diodes, and therefore light is emitted from the LED light display in a hemispherical direction. In fact, the purpose of traditional outdoor LED displays used in advertising has been to provide the best image quality at the widest possible view angles. As a result of this goal, most prior art outdoor LED displays share a few common optical features: wide-angle oval LEDs which provide wide horizontal view angles but at compressed vertical view angles; horizontal louvres on the physical faces of the LEDs which provide sun-shading and UV protection for the LEDs and improved visual contrast; and a layout of the red, green, and blue elements in each pixel in such a way that minimizes cross-blocking between pixels. Therefore, most outdoor LED displays have very similar optical performance across all manufacturers.

The result is that light emission is directed towards a target audience, as well as in the direction of other environments where the target audience is not present. Light trespass, which is the emission of light into areas where the target audience is not present and where there is no purpose for the light to be emitted, occurs and can in fact be a source of consternation for areas that are sensitive to light trespass. For example, residential neighborhoods, airport facilities, and protected nature reserves are all areas which are highly intolerant to light trespass, and traditionally would prevent or block the authorization for and installation of an LED display.

Some prior art LED light displays incorporate louvres for the purpose of either shading the LED diodes or blocking light emission in particular directions from such diodes. Such louvres can be utilized to reduce brightness of a LED display, but do so in a manner that reduces or entirely blocks visibility of the LED display from certain angles.

The emission of light into an environment by LED displays during nighttime use is increasingly an outcome that is being limited by regulation. In a similar manner to light trespass, such emission of light by a LED display can generate a number of detrimental environmental effects, including light pollution, interrupting the sleep patterns of persons living within a vicinity where the bright lights reach, behavior of animals (e.g., travel paths of animals drawn to the light, such as the flight path of migratory birds), etc. In recent years there is an additional level of public concern for the preservation of dark skies at night with regulations limiting light output above the horizon (upwards lighting) for outdoor lighting luminaires including billboard lights.

LED billboards currently outperform static light billboards that direct light along or above a horizontal plane, in terms of dark skies performance intrinsically by the use of horizontal louvres to shade the LEDs and to block or limit the optical output going in upwards direction. The configuration of these louvres and LEDs are, however, designed for LED billboard visual effectiveness, and not explicitly designed for reducing upwards lighting, thus being only somewhat effective at the latter. Additionally, the static billboards can be illuminated to a lower luminance level than digital billboards owing to specific limitations in digital billboards.

### SUMMARY

In accordance with an aspect, there is provided a LED display including: at least one pixel, each pixel having three subchannels arranged in a triangular configuration; and a control system configured to actuate any one or more of a downsampling mode or a temporal scanning mode of the LED display.

In some embodiments, the three subchannels comprise a red LED, green LED, and a blue LED, the blue LED positioned below the red LED and the green LED.

In some embodiments, a height of the triangular configuration is less than the width of the triangular configuration.

In some embodiments, each subchannel is secured to a circuit board by inline clinching.

In some embodiments, the LED display further includes at least one louvre positioned above at least one pixel.

In some embodiments, the LED display further includes a control system operable to switch between the downsampling mode, the temporal scanning mode, and a normal mode.

In some embodiments, the control system is operable to switch between the downsampling mode, the temporal scanning mode, and the normal mode based on a detected light level around the LED display.

In some embodiments, the LED display further includes at least one lens associated with at least one subchannel, the at least one lens configured to direct light emitted from the at least one subchannel downwards below a horizontal plane.

In some embodiments, an angle at which the light is directed is in a range of about 5° to about 15° below the horizontal plane.

In some embodiments, the downsampling mode comprises a pixel pitch of two times P, where P is the distance between two adjacent pixels, and three out of every four pixels are off.

In some embodiments, the downsampling mode comprises a pixel pitch of P times square root of two, where P is the distance between two adjacent pixels, and two out of every four pixels are off.

In some embodiments, the downsampling mode comprises, for each pixel, two subchannels being off and one subchannel being on.

In some embodiments, the subchannels that are on are red, red, green, and blue (RRGB), or green, red, green, blue (GRGB), or blue, red, green, blue (BRGB) in a grid of 2×2 pixels of the LED display.

In some embodiments, the temporal scanning mode comprises only one pixel being on in a grid of 2×2 pixels of the LED display for each quarter of a frame time, with a different pixel being on in each quarter of the frame time.

In some embodiments, the temporal scanning mode comprises only two diagonal pixels being on in a grid of 2×2 pixels of the LED display for each half of a frame time, with a different pixel being on in each half of the frame time.

In some embodiments, the temporal scanning mode comprises only red subchannels being on in a red third of a frame time, only green subchannels being on in a green third of the frame time, and only blue subchannels being on in a blue third of the frame time.

In some embodiments, the temporal scanning mode comprises only one subchannel being on in each pixel in each third of a frame time.

In accordance with an aspect, there is provided a method for reducing brightness of an LED display, the method including: arranging three subchannels in a triangular configuration in a pixel; and actuating one or more of a downsampling mode or a temporal scanning mode of the LED display.

In some embodiments, the method further includes positioning a blue LED below a red LED and a green LED, each as one of the three subchannels in the pixel.

In some embodiments, the method further includes inline clinching the three subchannels to a circuit board, wherein the triangular configuration has a height that is less than its width.

In some embodiments, the method further includes directing light emitted from the pixel downwards.

In some embodiments, the method further includes switching between the downsampling mode, the temporal scanning mode, and a normal mode.

In some embodiments, the switching is based on a detected light level around the LED display.

In some embodiments, the method further includes directing direct light emitted from at least one of the three subchannels downwards below a horizontal plane.

In some embodiments, an angle at which the light is directed is in a range of about 5° to about 15° below the horizontal plane.

In some embodiments, the method further includes, in the downsampling mode, actuating a pixel pitch of two times P, where P is the distance between two adjacent pixels, and three out of every four pixels are off.

In some embodiments, the method further includes, in the downsampling mode, actuating a pixel pitch of P times square root of two, where P is the distance between two adjacent pixels, and two out of every four pixels are off.

In some embodiments, the method further includes, in the downsampling mode, actuating for each pixel, two subchannels being off and one subchannel being on.

In some embodiments, the subchannels that are on are red, red, green, and blue (RRGB), or green, red, green, blue (GRGB), or blue, red, green, blue (BRGB) in a grid of 2×2 pixels of the LED display.

In some embodiments, the method further includes, in the temporal scanning mode, actuating only one pixel being on in a grid of 2×2 pixels of the LED display for each quarter of a frame time, with a different pixel being on in each quarter of the frame time.

In some embodiments, the method further includes, in the temporal scanning mode, actuating only two diagonal pixels being on in a grid of 2×2 pixels of the LED display for each half of a frame time, with a different pixel being on in each half of the frame time.

In some embodiments, the method further includes, in the temporal scanning mode, actuating only red subchannels being on in a red third of a frame time, only green subchannels being on in a green third of the frame time, and only blue subchannels being on in a blue third of the frame time.

In some embodiments, the method further includes, in the temporal scanning mode, actuating only one subchannel being on in each pixel in each third of a frame time.

### BRIEF DESCRIPTION OF THE DRAWINGS

Embodiments will be understood and become apparent when consideration is given to the following detailed description thereof. Such description makes reference to the annexed drawings wherein:

FIG. 1 is a depiction of a colour pattern in a LED display pixel in prior art LED displays;

FIG. 2 is a depiction of a colour pattern in a LED display pixel in prior art LED displays;

FIG. 3 is a depiction of a colour pattern in a LED display pixel in the LED display, according to some embodiments;

FIG. 4 is a depiction of a series of colour patterns forming LED pixels in prior art LED displays;

FIG. 5 is a depiction of a series of colour patterns forming LED pixels in the LED display, according to some embodiments;

FIG. 6 is a depiction of a series of colour patterns forming LED pixels in the LED display, according to some embodiments;

FIG. 7A is a schematic view of an LED arrangement in a pixel, according to some embodiments;

FIG. 7B is a schematic view of an LED arrangement in a pixel, according to some embodiments;

FIG. 7C is a schematic view of an LED arrangement in a pixel, according to some embodiments;

FIG. 7D is a schematic view of an LED arrangement in a pixel, according to some embodiments;

FIG. 8 is a schematic view of an LED arrangement in a pixel, according to some embodiments;

FIG. 9 is a schematic view of a collection of pixels in an LED display, according to some embodiments;

FIG. 10 is a schematic view of a collection of pixels in an LED display implementing a downsampling feature, according to some embodiments;

FIG. 11 is a schematic view of a collection of pixels in an LED display implementing a downsampling feature, according to some embodiments;

FIG. 12 is a schematic view of a collection of pixels in an LED display implementing a downsampling feature, according to some embodiments;

FIG. 13 is a schematic view of a collection of pixels in an LED display implementing a downsampling feature, according to some embodiments;

FIG. 14 is a schematic view of a collection of pixels in an LED display implementing temporal scanning, according to some embodiments;

FIG. 15 is a schematic view of a collection of pixels in an LED display implementing temporal scanning, according to some embodiments; and

FIG. 16 is a schematic view of a collection of pixels in an LED display implementing temporal scanning, according to some embodiments.

In the drawings, embodiments are illustrated by way of example. It is to be expressly understood that the description and drawings are only for the purpose of illustration and as an aid to understanding, and are not intended as a definition of any limits.

### DETAILED DESCRIPTION

Before explaining at least one embodiment in detail, it is to be understood that the embodiments are not limited in its application to the details of construction and to the arrangements of the components set forth in the following description or illustrated in the drawings. Other embodiments are capable of being practiced and carried out in various ways. Also, it is to be understood that the phraseology and terminology employed herein are for the purpose of description and should not be regarded as limiting.

Unless otherwise stated or clearly understood herein, the following understandings are provided. References herein to individual LEDs are understood to be subpixel channels (or other collection of light-emitting units) in other embodiments. References herein to individual pixels are understood to be collections of light-emitting units in other embodiments. References to a pixel or LED that is “on” is understood to refer to, in various different embodiments, emission of light at any one level of emission, including at a maximum brightness or less than a maximum brightness. References to a pixel or LED that is “off” is understood to refer to no emission of light. Values herein are understood to include the value references as well as values within a +/−10%, inclusive, range from that value. “About” includes the value which it is used to described as well as values within +/−10%, inclusive.

The specific limitation of LED billboards at very low brightness is related to the way individual LEDs are driven, typically by a combination of a constant current drive and a Pulse Width Modulation (PWM). An individual diode component has an active diode region that operates within a certain range of current densities where the region can uniformly achieve light output. At night time, to achieve low maximum brightness while maintaining visual quality and uniformity, the current density must be maintained by use of PWM which turns on and off each LED channel in pulses at its nominal current density but provides the pulse width using a digital counter of a fixed number of bits (bit depth). The same bits are used for creating different pixel levels in image reproduction as well as setting the overall maximum brightness. In this way, at very low maximum brightness settings, many Most Significant Bits are set to zero to lower the brightness and the LED billboard no longer has enough available Least Significant Bits remaining to reproduce images accurately, resulting in colour bands and steps where instead colour gradients were intended. Both channel current density and PWM bit depth are fundamental limitations to digital billboards for very low brightness image production.

What is needed is a LED display that provides a digital billboard that operates to optimally preserve the night sky darkness, but way of directional reduction of horizontal and above horizontal plane lighting emitted from such LED display, a reduction of the minimum working brightness of digital billboards, and technologies that optimize or maximize the above-horizon shading and methods to allow digital billboards to operate at ever lower levels of total brightness. Prior art LED displays cannot achieve such outcomes in a manner that meets or exceeds regulations relating to light pollution. What is needed to address this gap is a LED display configured to display at a brightness that has a diminished impact on the surrounding environment, while maintaining a clear and visible display of text, graphics and any combination thereof from the LED display. Embodiments as described herein can provide an altered direction for the light emitted from a LED diode in a LED display due to a lens configuration that directs light downward from the horizontal point, and RBG pixel combinations wherein the blue colour is positioned below the red and green colours in the pixel colour groupings. Louvres may also be positioned to further dim brightness in particular directions of light emission from one or more LED diodes within a LED display.

Embodiments described herein are a LED display that is operable throughout the day and night, and during nighttime in particular displays clear and visible text and/or graphics in a manner that meets light pollution regulations by reducing the light emitted from the LED display along or above a horizontal plane. In particular, in some embodiments, the LED display incorporates one or more LED diodes having a lens directs the majority of light emission therefrom below the horizontal plane, implements louvres to alter the direction of the emission form the diodes, incorporates colour patterns that position the blue colour below the red and green colours in a LED pixel, and incorporates colour patterns wherein blue light from some pixels is not displayed.

Creating a LED display that meets the light pollution LED regulations cannot merely be achieved by utilizing prior art LED displays at settings of reduced brightness. Such an approach is not workable as it reduces the brightness of the LED display, but as a result also diminishes the clarity and visibility of the text and graphics displayed by such LED display.

In some embodiments, the LED display incorporates LED diodes configured with a dial lens whereby the mass of light is not emitted from the center of the LED diode along a horizontal plane. Instead the lens is configured such that the centroid of the radiation pattern and the maximum output of the mass of light emitted from the LED diode is directed in a downward direction from the horizontal plane (e.g. downward from 0 degrees horizontal, for example such as at an angle in a range from −3 degrees to −20 degrees such as −5 degrees or −10 degrees or −3 degrees or −15 degrees, or, alternatively, another angle below horizontal). Such lens reduces the light emitted by the LED along the horizontal plane and thereby causes less light to travel along or above a horizontal plane from the LED display. This diminishes the light pollution and light trespass created by the LED display.

This configuration offers a benefit over the prior art. Prior art LED diodes incorporate lenses that emit light along a horizontal plane or above the horizontal plane. Such prior art lenses direct the light emissions therefrom along or above the horizontal plane where it is extends significant distances into the surrounding environment and thereby creates significant brightness in such environment which causes light pollution and light trespass.

Embodiments may further incorporate one or more louvres each positioned proximate to a LED diode in a manner whereby such louvre blocks light emitted from the LED diode in an upwards direction. Such louvres limit light emission from the LED diode that is directed from the LED diode in an upwards direction that is blocked by a louvre, and thereby reduce light emissions of the LED display in such upwards direction. The upward viewing angle for the LED display may be increased due to the size and layout of the LED pixels. In embodiments, LED diodes can be placed as physically upward as possible in the LED display, to thereby leverage mechanical placement of diodes to increase the rate of reduction of light being emitted in an upward direction.

Embodiments also spread pixels in a LED display out from one another along a horizontal or virtually horizontal line, as much as possible without losing clarity of the text and graphics displayed by such LED display.

This aspect creates a benefit over the prior art, as the prior art clusters pixels, and does not spread the pixels out over a horizontal plane. Prior art LED displays thereby increase light pollution due to an increased upward exposure of diodes relative to any horizontal louvres.

The discussion below provides information about some embodiments. A skilled reader will recognize that this discussion provides examples of possible embodiments, and that other embodiments are also possible.

Embodiments further arrange the colours in each pixel 20 in the LED display so as to position the blue light 22 below the red light 26 and green light 24, as shown in FIG. 3. Blue light has the lowest luminance emission measured in candelas/m\hat{ }2. A blue light provides 10% of the emissions from a red blue green (RBG) coloured pixel. In such a configuration, a LED display that incorporates a louvre above the LED pixel will result in the blue light being the last colour that is not blocked as an upward viewing angle (being upward from the horizontal viewing angle) of the LED display increases.

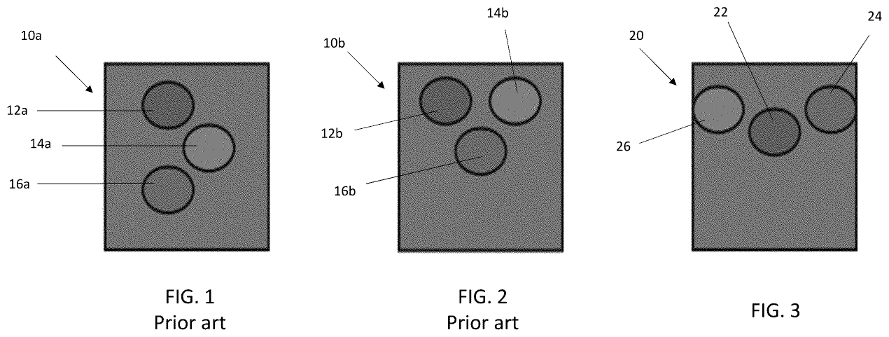

This aspect creates a benefit over the prior art, as (as shown in FIGS. 1 and 2) the prior art LED display pixels 10a, 10b incorporate colour patterns where the blue colour 12a, 12b is above the red colour 14a, 14b and green colour 16a, 16b (as shown in FIG. 1), or is not below both the red and green lights in a pixel (as shown in FIG. 2). This design in prior art is for the intention of maximizing sun shielding by the louvres on to the blue colour, which is traditionally the most vulnerable to ultraviolet degradation.

As light emissions during the nighttime creates significant light pollution and light trespass, embodiments further limit blue light emission through only utilizing some of the blue colours in LED pixels in a LED display when such display is utilized at nighttime. For example, as shown in FIGS. 5 and 6, multiple colour patterns can be arranged into a pixel collection 32, 34 wherein blue light 22a, 22d can be turned on (to emit light) in every other pixel, and the blue light 22c, 22b in the other pixels can be turned off (to not emit light) in a LED display when a LED display is utilized at night. The red lights 26a, 26b, 26c, 26d, 26e, 26f, 26g and green lights 24a, 24b, 24c, 24d, 24e, 24f, 24g can all be turned on in the pixel collection. This sub-pitch nighttime configuration can balance out the light of the LED display when it is in use during the nighttime (being the hours when the sun is not shining upon the LED display).

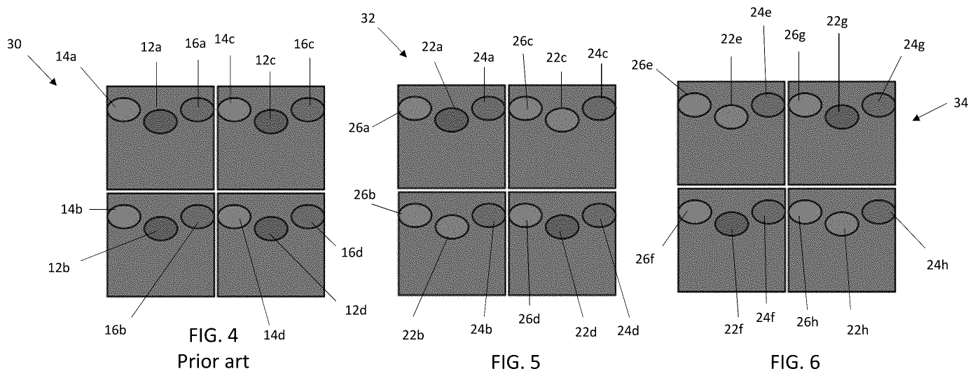

This aspect creates a benefit over the prior art, as (as shown in FIG. 4) the prior art LED display pixel collection 30 incorporates colour patterns wherein the blue colour 12a, 12b, 12c, 12d, is not below the red colour 14a, 14b, 14c, 14d and green colour 16a, 16b, 16c, 16d, and all colours are turned on.

Embodiments may further incorporate a further sub-pitch LED configuration, whereby in an RGB pixel the red and green light are utilized at one resolution level and the blue light is at a different resolution.

Embodiments may further incorporate video processing and LED electronic drive techniques that enable ultra-low brightness imaging while mitigating limitations of low brightness drive. For example, a key limitation of an ultra-low brightness drive is bit-depth in pulse width modulation (PWM) and current density in LED diodes. In some embodiments, LED diode grayscale is realized by a constant current drive circuit operated with PWM. The bit depth in PWM limits the available number of bits to render grayscale at the lowest brightness settings. A method that changes “modes” can be implemented that reduces the current setting when a low brightness mode is chosen, to thereby preserve bit depth. Modes of a LED display may be controlled by digital technology linked to the LED. The digital technology may further be linked to sensors (e.g., sensors of light in the environment of the LED display) and to timers (e.g., timers that cause a change of the LED display modes based upon the time of day, such as evening, nighttime, morning and daytime hours).

Notably, lower current setting will affect the performance of LED chips. This will create colour changes and low current density can also cause non-uniformity amongst LED diodes. The colour change effect can be addressed by a color-channel compensation. The reduction in uniformity can be addressed by an individual channel compensation. Embodiments can incorporate methods of use of the LED display to maintain LED display peak currents and to mitigate such challenges. A “multi-layer time multiplex” is one such method that utilizes a combination of a standard time-multiplex and an additional orthogonal control-system time-multiplex. Furthermore, a method of a sub-pitch drive, whereby a blue light (positioned below a red and green light in a pixel) may be set from a drive of ½ the pixel count to ¼ pixel count (for example 20 mm becomes 20×sqrt (2)=28 mm or 20 mm becomes 40 mm). This method leverages the natural human eye reduction in spatial resolution at any low brightness, and does not reduce the quality of the text and/or graphics displayed by the LED display (as viewed by a viewer of the LED display) to a point of a lack of clarity or visibility to viewers of such LED display.

### Other LED Arrangements

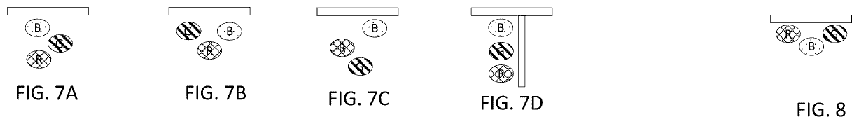

FIG. 7A shows an example arrangement of a pixel where blue, green, and red LEDs are arranged in a triangular configuration with the blue LED positioned at the top, green LED positioned at the right, and red LED positioned at the bottom. (In some embodiments, the positioning of the green and red LEDs can be reversed.) This provides a suitable packing and a suitable pixel pitch. FIG. 7B shows an example arrangement of a pixel where blue, green, and red LEDs are arranged in a triangular configuration with the blue LED positioned at the right, green LED positioned at the left, and red LED positioned at the bottom. This provides improved blue LED protection and overall sun shading when spacing is available in a wider pixel pitch Configurations shown in FIGS. 7A and 7B can be improved by embodiments described herein. In each configuration in FIGS. 7A, 7B, 7C, and 7D, the blue LED is positioned in the highest position for shielding under a louvre, whereas in embodiments described herein, the blue LED can be positioned below the red and green LEDs and described herein.

FIG. 7C shows an example arrangement of a pixel that provides an alternate prior art design featuring a very wide view angle when viewed from slightly below and blue LED protection. FIG. 7D shows an example arrangement of a pixel that provides accurate horizontal blocking.

### Example Embodiments

Embodiments described herein may help reduce light emitted by LED displays, such as to reduce light emitted during nighttime or reduce light pollution in nighttime skies. The arrangement of LEDs in a pixel, as well as on/off patterns can be used to address these aims.

As blue LEDs are most vulnerable to the sun and can degrade the fastest compared to other colour LEDs, they are in prior art positioned above the other colour LEDs. However with improved blue LED materials and construction they are more resistant to sun and degradation, and these blue LEDs can be positioned below the other colour LEDs in a pixel (when viewed at the desired viewing angle). Also, as a blue LED has the lowest light emission compared to red or green LEDs, this arrangement can help limit the total upward brightness.

### Shielding Device

In some embodiments, one or more louvres can be included to direct or block the emission of light in an upwards direction or other direction. This can help reduce light emission and light pollution. Louvres can also be used to help protect the LED display from UV or sun damage. For example, LEDs in a pixel can be placed as high as possible such that the LEDs are as close as possible under a louvre. This can help provide a maximum shielding by the louvre which can provide sun-shading and UV protection for the LEDs and improved visual contrast. In some embodiments, instead of a louvre, a different shielding device can be used.

### Lens for Down-Angle LED Light Emission

In some embodiments, a lens is arranged at or included in a LED or collection of LEDs. The lens is configured to direct light emitted from the associated LED(s) in a downward direction from the horizontal plane (e.g., downward from 0 degrees horizontal, for example such as at an angle in a range from −3 degrees to −20 degrees such as −5 degrees or −10 degrees or −3 degrees or −15 degrees, or, alternatively, another angle below horizontal). Such lens reduces the light emitted by the LED along the horizontal plane and thereby causes less light to travel along or above a horizontal plane from the LED display, in some embodiments. This can diminish the light pollution and light trespass created by the LED display.

### Arrangement of LEDs in a Pixel

FIG. 8 shows an example arrangement of a pixel according to some embodiments that provides a maximized width, maximized total protection, and minimized upward viewing luminance. Advantageously, the blue LED is arranged at the bottom of a triangular configuration of LEDs with a red LED and green LED positioned above the blue LED.

In some embodiments, each LED in a pixel is packed tightly together. Instead of end clinching of the LEDs in a pixel, some embodiments provided herein use inline clinching. This provides a significant advantage of allowing the LEDs in a pixel to be packed more tightly together, resulting in a flatter (less height) triangular arrangement of the LEDs in the pixel, according to some embodiments. Inline clinching is provided by inserting the pins of each LED through holes of the circuit board behind the LED and bending the pins in the same direction in a line, rather than end clinching the pins by bending the pins of each LED in opposite directions. Inline clinching allows pixels and LEDs in each pixel to be packed more tightly vertically. This can advantageously increase or help maximize the blocking effect of the red and green LEDs on the lower blue LED, according to some embodiments.

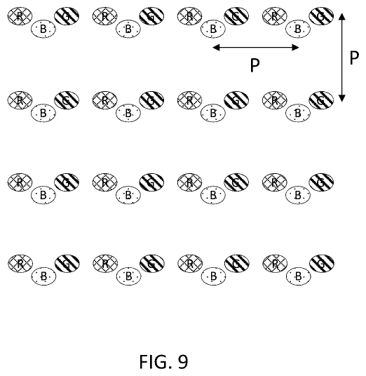

FIG. 9 shows an example collection of pixels in an LED display, according to some embodiments. Each pixel includes a triangular arrangement of LEDs, with a red LED and a green LED positioned above a blue LED. In some embodiments, the triangular arrangement is configured as a flat triangle with its height less than its width, for example, as provided by inline clinching of each LED in the pixel. In FIG. 9, “P” denotes the pixel pitch measured between neighbouring pixels that are emitting light (“on”). In the example shown, the pixel pitch measured in a horizontal direction from the blue LEDs of neighbouring pixels is equal to the pixel pitch measured in a vertical direction from the green LEDs (or, alternatively, red LEDs) of neighbouring pixels. In some embodiments, the positioning of the red and green LEDs in a pixel may be different or the same as the positioning of the red and green LEDs in a neighbouring pixel or other pixel in the LED display. In some embodiments, and in the example shown in FIG. 9, the LED display operates in a normal drive mode, with all LEDs in all pixels emitting light (“on”).

### Spatial Downsampling of Pixels

In some embodiments, the light emitted by an LED display can be reduced by spatially downsampling the pixels in the LED display. For example, individual subpixel channels or individual pixels can be turned “off” (no or less light emitted). This can be implemented by applying a mask on the input frame data to actively control which pixels or subpixel channels are “on” and which are “off”. This can provide a controlled manner of reduction in brightness or light pollution of an LED display, but may reduce spatial resolution of the LED display. However, in low light, the human visual system loses spatial resolution perception. Accordingly, in some embodiments, the LED display is switchable to a mode that implements this feature on request or automatically when atmospheric light conditions fall below a pre-programmed threshold level. A very low brightness limit may be required by law when the display is installed in areas of low ambient light at night, such as minimally illuminated roadways or non-illuminated roadways. In some embodiments, where the LED display is positioned for viewing up close, temporal scanning methods can be favoured for use over spatial downsampling methods. In some embodiments, where it is desired to have a lower power or computational or drive circuitry cost or design, spatial downsampling methods can be favoured for use over temporal scanning methods. In some embodiments, a control system is included in the LED display to configure or control the actuation of this mode or feature or any other mode or feature described herein. The control system may include network or remote connectivity between the LED display and a remote computer. In some embodiments, the control system is configured to actuate spatial downsampling of pixels or subchannels of pixels at the LED display upon detection of low light conditions below a threshold level of light, such as during nighttime conditions, or actuate at a fixed time in a programmed schedule, or some combination of input conditions. In some embodiments, the actuation is upon demand such as received via user input at a user interface.

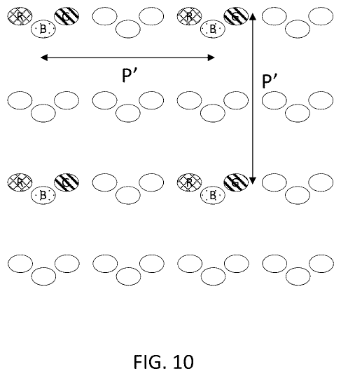

FIG. 10 shows an example configuration of pixels in an LED display implementing a downsampling feature, according to some embodiments. In the example shown, the pixel pitch (distance between adjacent pixels that are “on”) is denoted by P′, which is two times the P shown in FIG. 9. This can provide a 75% reduction on the minimum brightness of the LED display, with ¼ of the pixels “on” and ¾ of the pixels “off”. A loss of only half of the pixel resolution may result with a doubling of the pixel pitch. This reduction in minimum brightness is achieved without any reduction in the current density or PWM bit depth, allowing the on-state LEDs to operate in their nominal operating condition. The brightness is reduced via lowered effective pixel pitch but preserving visual uniformity and smooth gradient rendering.

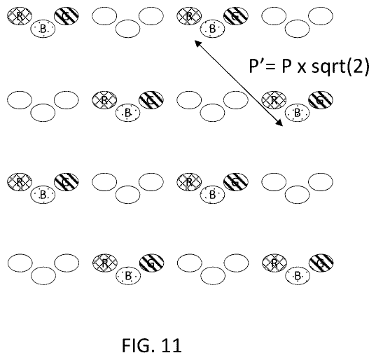

FIG. 11 shows an example configuration of pixels in an LED display implementing a downsampling feature that is 1 pixel on, 1 pixel off, or alternating pixels according to some embodiments. In the example shown, the pixel pitch (distance between adjacent pixels that are “on”) is denoted by P′, which is the P shown in FIG. 9 times the square root of two. This can provide a 50% reduction on the minimum brightness of the LED display, with ½ of the pixels “on” and ½ of the pixels “off”. In this example, the pixel pitch is increased by the square root of two which is approximately 1.41. This again reduces the brightness by a smaller change to pixel pitch and preserving visual uniformity and smooth gradient rendering.

In some embodiments, subchannels of a pixel are downsampled or selectively “on” or “off”. A subchannel can be a collection of LEDs or a single LED, such as emitting a single colour type.

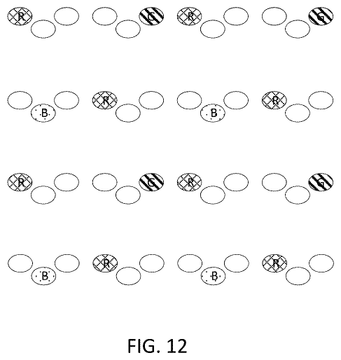

FIG. 12 shows an example configuration of pixels in an LED display implementing a downsampling feature in subchannels of each pixel, according to some embodiments. In the example shown, two of three subchannels of each pixel are disabled or “off”, with the specific subchannel “off” being alternated (e.g., different) by pixel. For example, this can leave an arrangement of RRGB LEDs active per 2×2 arrangement of pixels as shown in FIG. 12. This can provide a ⅔ or about 67% reduction in the minimum brightness of the LED display. Effectively, the pixel pitch is increased by two, but a level of light (or “fill”) is maintained such that dark or “off” gaps between pixels are mitigated, reduced, lessened, or not increased. In some embodiments, a different arrangement of coloured subchannels (or coloured LEDs) is “on” amongst a grouping of pixels. For example, this can be an arrangement other than RRGB, such as GRGB or BRGB and/or the repeated arrangement can be across an arrangement of pixels other than a 2×2 grid. The selection of the arrangements can be made to achieve a desired level of a desired baseline level of light between pixels or otherwise at the LED display and/or to maintain a desired level of spatial resolution or image quality. As yet another example, an arrangement of RGB LEDs can be “on” per 2×2 arrangement of pixels (one of every 2×2 pixels is disabled or off), or can leave an arrangement of RRGB LEDs active per 3×3 arrangement of pixels (five of every 3×3 pixels are disabled or off). The selection of the arrangements can be made to achieve a desired level of a desired baseline level of light between pixels or otherwise at the LED display and/or to maintain a desired level of spatial resolution or image quality.

### Temporal Scanning

In some embodiments, the light emitted by an LED display can be reduced by temporal scanning. For example, the arrangement of pixels (or subchannels) that are “on” or “off” can be rapidly changed over each time frame in a pattern that repeats over time. The speed at which this is performed can be pre-set or actuated by the control system. The speed can be selected based on the human visual system temporal resolution limitations in low light. In bright light, human photopic vision has a faster shorter integration time of 10-15 ms, but in low light, human scotopic vision integration time can be up to 100 ms. Temporal scanning can be operated in cycles without noticeable visual flickering if several cycles can be incorporated per integration time period. Some patterns of scanning will result in more noticeable flickering for a fixed scanning rate. Several embodiments are described for different patterns of scanning. In some embodiments, a control system is configured to actuate temporal scanning at the LED display upon detection of low light conditions below a threshold level of light, such as during nighttime conditions or actuate at a fixed time in a programmed schedule, or some combination of input conditions. In some embodiments, the actuation is upon demand such as received via user input at a user interface. For example, the duration of each time frame between change of the pattern of pixels (or subchannels) that are “on” or “off” is in a range from about 10 to about 70 ms in some embodiments. Advantageously, temporal scanning maintains spatial resolution.

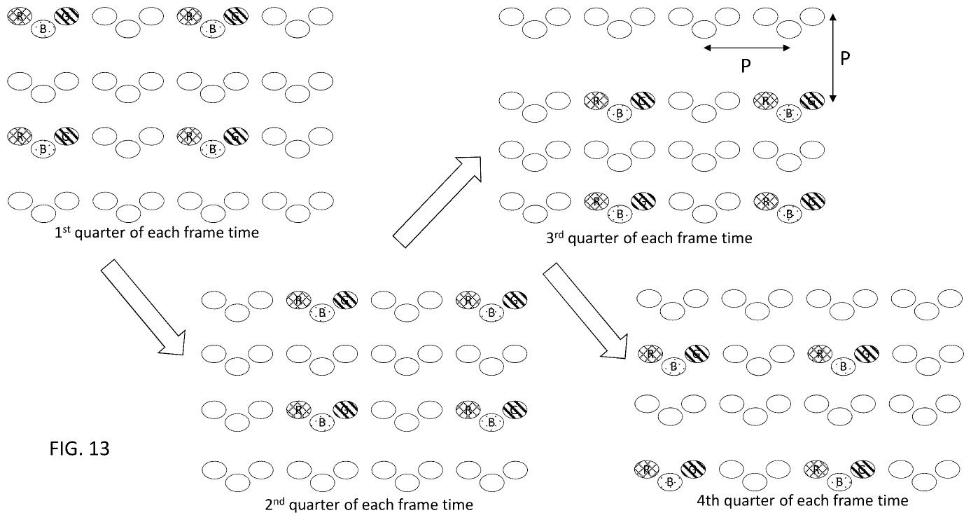

FIG. 13 shows an example method implementing temporal scanning at an LED display, according to some embodiments. Pixels are turned “on” in an arrangement over four quarters of each time frame, with all pixels “on” at some time over the course of the four quarters. While other selections of which pixels are “on” at each given time may be implemented in other embodiments, in the example shown in FIG. 13, at a first quarter of each time frame, the top left pixel in each of four adjacent 2×2 grids of pixels is “on” (where the four adjacent 2×2 grids of pixels are arranged in a 4×4 grid). At a second quarter of each time frame, the top right pixel in each of the four adjacent 2×2 grids of pixels is “on”. At a third quarter of each time frame, the bottom right pixel in each of the four adjacent 2×2 grids of pixels is “on”. At a fourth quarter of each time frame, the bottom left pixel in each of the four adjacent 2×2 grids of pixels is “on”. In FIG. 13, the pixel pitch is denoted by P.

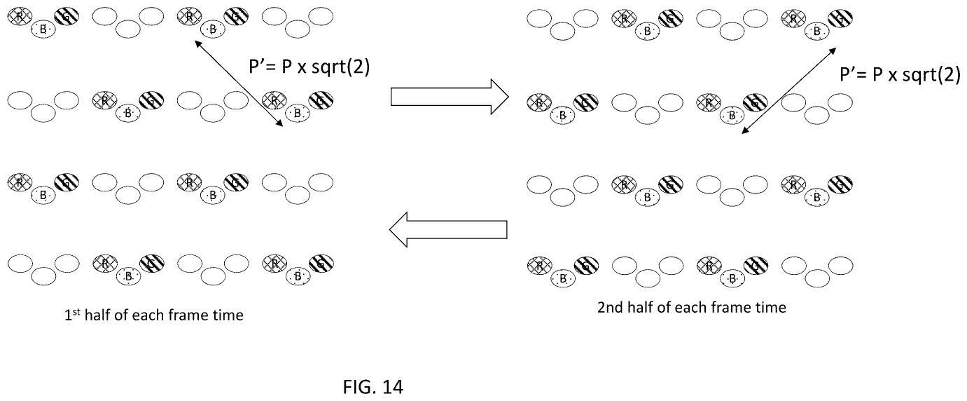

FIG. 14 shows an example method implementing temporal scanning at an LED display, according to some embodiments. Pixels are turned “on” in an arrangement over two halves of each time frame, with all pixels “on” at some time over the course of the two quarters. While other selections of which pixels are “on” at each given time may be implemented in other embodiments, in the example shown in FIG. 14, at a first half of each time frame, the top left and bottom right pixels in each of four adjacent 2×2 grids of pixels is “on” (where the four adjacent 2×2 grids of pixels are arranged in a 4×4 grid). At a second half of each time frame, the top right and bottom left pixels in each of the four adjacent 2×2 grids of pixels is “on”. In FIG. 13, the pixel pitch is denoted by P′, which is the square root of two times the pixel pitch P shown in FIG. 12. In the example shown, the brightness of the LED display is reduced by half. Each pixel, when “on”, can be at full brightness, but will be “on” only half of the time.

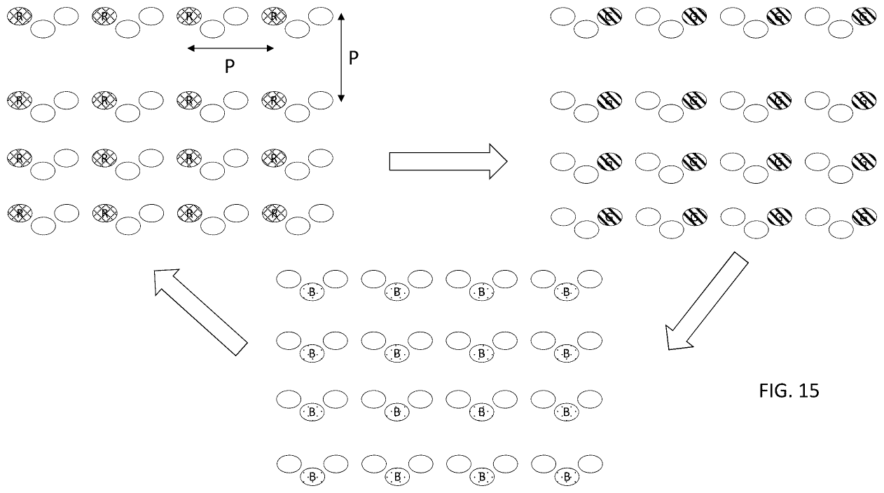

FIG. 15 shows an example method implementing temporal scanning at an LED display, according to some embodiments. LEDs (or subchannels) of pixels are turned “on” in an arrangement over thirds of each time frame, with all LEDs (or subchannels) “on” at some time over the course of the three thirds. In each third of each time frame, one LED or subchannel of each pixel is “on” and the other LEDs or subchannels in each pixel is “off”. While other selections of which pixels are “on” at each given time may be implemented in other embodiments, in the example shown in FIG. 15, in each third of each time frame, all the LEDs or subchannels of the same colour across the group of pixels is “on” while the other LEDs or subchannels in each pixel is “off”, with a different colour LED or subchannel “on” at the next third of a time frame and yet a further different colour LED or subchannel “on” at the final third of the time frame. In the example shown in FIG. 15, the first colour is red and all the red LEDs in each pixel are positioned at the top left of the triangular LED arrangement in each pixel. In the next third of the time frame in FIG. 15, all the green LEDs in each pixel are “on” and are positioned at the top right of the triangular LED arrangement in each pixel. In the final third of the time frame in FIG. 15, all the blue LEDs in each pixel are “on” and are positioned at the bottom of the triangular LED arrangement in each pixel. In some embodiments, a ⅔ or about 67% reduction in the minimum brightness is provided for an LED display implementing this temporal scanning arrangement. In this example, RGB are scanned per pixel over time and there is no loss of spatial resolution. The speed at which the pixel arrangements are changed and/or the duration of each time frame is set based on the temporal resolution of the human vision system, which is low at low light. This can be preset or configured by a control system.

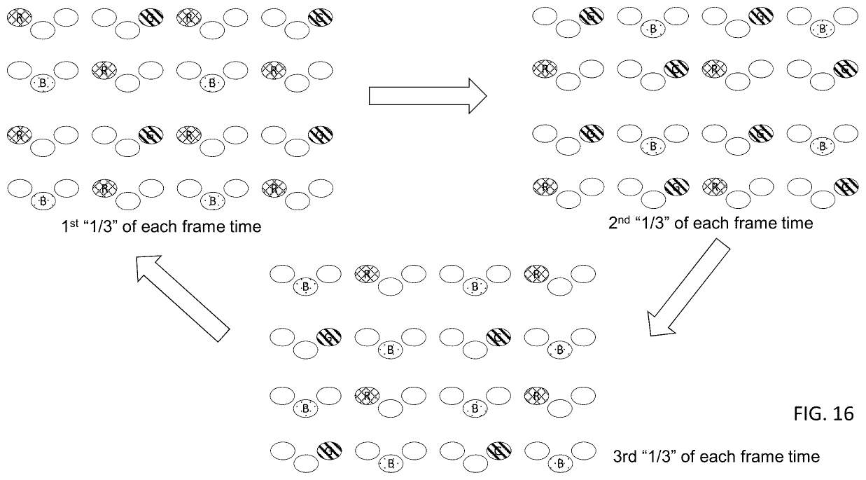

FIG. 16 shows an example method implementing temporal scanning at an LED display, according to some embodiments. LEDs (or subchannels) of pixels are turned “on” in an arrangement over thirds of each time frame, with all LEDs (or subchannels) “on” at some time over the course of the three thirds. In each third of each time frame, one LED or subchannel of each pixel is “on” and the other LEDs or subchannels in each pixel is “off”. While other selections of which pixels are “on” at each given time may be implemented in other embodiments, in the example shown in FIG. 16, in each third of each time frame, different coloured LEDs or subchannels across the group of pixels are “on”, with only one LED or subchannel “on” in each pixel, while the other LEDs or subchannels in each pixel is “off”, with a different LED or subchannel “on” in each pixel at the next third of a time frame and yet a further different LED or subchannel “on” in each pixel at the final third of the time frame. The LED colour “on” at a given time in a pixel can be different than the LED colour that is “on” at the same time in adjacent pixels. In the example shown in FIG. 16, the red LED in the first pixel is “on”, the green LED in the pixel to the right is “on”, and the blue LED in the pixel below is “on”, and in the next third of the time frame, these LEDs are turned “off” and the LED that is turned on in each pixel is the next LED in a clockwise direction, where each pixel has a triangular arrangement of LEDs with the top left as red, top right as green, and bottom as blue. In some embodiments, a ⅔ or about 67% reduction in the minimum brightness is provided for an LED display implementing this temporal scanning arrangement. In this example, RGB are scanned per pixel over time and there is no loss of spatial resolution. The speed at which the pixel arrangements are changed and/or the duration of each time frame is set based on the temporal resolution of the human vision system, which is low at low light. This can be preset or configured by a control system.

In some embodiments, temporal scanning is more complex to implement and takes more computational resources than spatial downsampling. Spatial downsampling is can be implemented by applying a mask over the input frame buffer such that desired “off” LEDs or pixels are switched to a value of zero. For temporal scanning, in some implementations, the timing of the scanning cycle is aligned with the PWM cycle such that each scanning cycle must have exactly an integer number of PWM cycles. Secondly, in order to achieve the scanning without timing errors or latency, frame buffers should be further divided into sub buffers in queue to send to driver integrated circuits. In some embodiments, temporal scanning is used when atmospheric light conditions are low or below a threshold light level (e.g., nighttime) determined to minimize human perception of movement in the image displayed from the change in which pixels are turned “on” over time. Spatial downsampling can also frontload the image processing upstream in the video stream, while temporal scanning requires generally more hardware resources distributed throughout the display system for displaying accurate images.

In some embodiments, only a fraction of the LEDs of the pixels in an LED display are turned “on” or emit light at a given time, and different LEDs are alternated between as being “on” over time. While on, the LEDs can drive at the same current density such that the quality of visual display to the human eye is not impacted beyond a threshold.

In some embodiments, a pixel can have a different number of LEDs, such as multiple LEDs of each colour.

### Control System

Other selections of “on” and “off” pixels can be provided according to various embodiments. In some embodiments, a LED display is capable of implementing one or more downsampling configurations and/or one or more time sampling configurations. In some embodiments, a control system is configured to actuate the different configurations, such as in response to atmospheric conditions (brightness from daytime or nighttime), temperature, a threshold level of brightness, the brightness or nature of image(s) to be displayed on the LED display as represented by data received by or caused to be displayed by control system, estimated or measured level of light emission from the LED display, or a combination thereof. In some embodiments, the control system includes a processor configured to execute instructions in memory to drive the actuation of the pixel (or subchannel) arrangement, whether in a temporal pattern or spatial pattern or both. In some embodiments, the control system can switch between a normal mode (an example of which is shown in FIG. 9), spatial downsampling mode (examples of which are shown in FIGS. 10, 11, and 12), and/or temporal scanning mode (examples of which are shown in FIGS. 13, 14, 15, and 16), such as on request or in response to detected conditions or desired levels of light emission or the nature or brightness or other attribute of image(s) to be displayed at the LED display. For example, where spatial resolution is detected as desired to be maintained (e.g., based on higher brightness levels in the atmosphere as daylight conditions dim or the nature of the image to be displayed at the LED display), control system may actuate a temporal scanning mode, and where spatial resolution is detected as less desired to be maintained (e.g., based on low to no brightness levels in the atmosphere such as in the middle of the night), control system may actuate a spatial downsampling mode. The particular configuration in each mode is controllable by control system, can be in response to detected conditions or desired levels of light emission or an attribute of image(s) to be displayed at the LED display, and/or may be preset in data accessible from a data store by control system.

In some embodiments, there is provided a LED display including at least one pixel, each pixel having three subchannels arranged in a triangular configuration; and a control system configured to actuate any one or more of downsampling mode or a temporal scanning mode of the LED display. For example, a single LED display can be capable of only a downsampling mode and a normal mode. As another example, a single LED display can be capable of only a temporal scanning mode and a normal mode. As another example, a single LED display can be capable of only a temporal scanning mode and a downsampling mode and a normal mode.

Described herein is a LED display that is operable throughout the day and night, and during nighttime in particular displays clear and visible text and/or graphics in a manner that meets light pollution regulations by reducing the light emitted from the LED display along or above a horizontal plane. In particular, in some embodiments, the LED display incorporates one or more LED diodes having a lens directs the majority of light emission therefrom below the horizontal plane, implements louvres to alter the direction of the emission form the diodes, incorporates colour patterns that position the blue colour below the red and green colours in a LED pixel, and incorporates colour patterns wherein blue light from some pixels is not displayed.

In some embodiments, the LED display includes one or more pixels having a blue light positioned below a red and a green light in such pixel.

In some embodiments, the blue light in the LED display is turned off in every other of the one or more pixels.

In some embodiments, each of the one or more pixels incorporates one or more LED diodes each incorporating a lens directing a mass of light emitted from said LED diode below a horizontal plane.

It will be appreciated by those skilled in the art that other variations of the embodiments described herein may also be practiced. Other modifications are therefore possible.

What is claimed is:

1. A LED display comprising:
at least one pixel, each pixel having three subchannels arranged in a triangular configuration; and
a control system configured to actuate any one or more of a downsampling mode or a temporal scanning mode of the LED display.

2. The LED display of claim 1, wherein the three subchannels comprise a red LED, green LED, and a blue LED, the blue LED positioned below the red LED and the green LED, wherein a height of the triangular configuration is less than the width of the triangular configuration.

3. The LED display of claim 1, further comprising a control system operable to switch between the downsampling mode, the temporal scanning mode, and a normal mode.

4. The LED display of claim 3, wherein the control system is operable to switch between the downsampling mode, the temporal scanning mode, and the normal mode based on a detected light level around the LED display.

5. The LED display of claim 1, further comprising at least one lens associated with at least one subchannel, the at least one lens configured to direct light emitted from the at least one subchannel downwards below a horizontal plane.

6. The LED display of claim 1, wherein the downsampling mode comprises a pixel pitch of two times P, where P is the distance between two adjacent pixels, and three out of every four pixels are off.

7. The LED display of claim 1, wherein the downsampling mode comprises a pixel pitch of P times square root of two, where P is the distance between two adjacent pixels, and two out of every four pixels are off.

8. The LED display of claim 1, wherein the downsampling mode comprises, for each pixel, two subchannels being off and one subchannel being on.

9. The LED display of claim 1, wherein the temporal scanning mode comprises only one pixel being on in a grid of 2×2 pixels of the LED display for each quarter of a frame time, with a different pixel being on in each quarter of the frame time.

10. The LED display of claim 1, wherein the temporal scanning mode comprises only two diagonal pixels being on in a grid of 2×2 pixels of the LED display for each half of a frame time, with a different pixel being on in each half of the frame time.

11. The LED display of claim 1, wherein the temporal scanning mode comprises only red subchannels being on in a red third of a frame time, only green subchannels being on in a green third of the frame time, and only blue subchannels being on in a blue third of the frame time.

12. The LED display of claim 1, wherein the temporal scanning mode comprises only one subchannel being on in each pixel in each third of a frame time.

13. A method for reducing brightness of an LED display, the method comprising:
arranging three subchannels in a triangular configuration in a pixel, wherein a blue subchannel is below a red subchannel and a green subchannel; and
actuating one or more of a downsampling mode or a temporal scanning mode of the LED display.

14. The method of claim 13, further comprising inline clinching the three subchannels to a circuit board, wherein the triangular configuration has a height that is less than its width.

15. The method of claim 13, further comprising directing light emitted from the pixel downwards about 5° to about 15° below the horizontal plane.

16. The method of claim 13, further comprising switching between the downsampling mode, the temporal scanning mode, and a normal mode.

17. The method of claim 13, further comprising, in the downsampling mode, actuating a pixel pitch of a factor of P, where P is the distance between two adjacent pixels, and a selection of pixels are off at a given time.

18. The method of claim 13, further comprising, in the downsampling mode, actuating for each pixel, a selection of subchannels being off at a given time.

19. The method of claim 13, further comprising, in the temporal scanning mode, actuating only a selection of pixel being on in a grid of 2×2 pixels of the LED display for each fraction of a frame time, with a different pixel being on in each fraction of the frame time.

20. The method of claim 13, further comprising, in the temporal scanning mode, actuating only a selection of subchannels being on in each pixel in each fraction of a frame time.
